(19) United States
(12) Patent Application Publication
(10) Pub. No.: US 2024/0155854 A1
(43) Pub. Date: May 9, 2024

(54) COMPOSITE ELECTRODE STRUCTURE AND METHOD FOR MANUFACTURING THE SAME

(71) Applicant: National Tsing Hua University, HSINCHU CITY (TW)

(72) Inventors: TZU-CHIEN WEI, HSINCHU CITY (TW); TZU-SEN SU, Yilan County (TW); HAN-TU LIN, Hsinchu County (TW); SHIANG LAN, Taoyuan City (TW)

(21) Appl. No.: 18/499,220

(22) Filed: Nov. 1, 2023

(30) Foreign Application Priority Data
Nov. 4, 2022 (TW) 111142216

(51) Int. Cl. H10K 30/82

(52) U.S. Cl. CPC H10K 30/82; H10K 30/50

(57) ABSTRACT

A composite electrode structure and a method for manufacturing the same are provided. The composite electrode structure is used as a back electrode of a perovskite solar cell. The composite electrode structure includes a first conductive layer and a second conductive layer. The first conductive layer is used to connect with an electron transporting layer or a hole transporting layer. A material of the first conductive layer is a first light transmitting conductive oxide. The second conductive layer is disposed on the first conductive layer. A material of the second conductive layer is a second light transmitting conductive oxide or a conductive metal.

### CROSS-REFERENCE TO RELATED PATENT APPLICATION

This application claims the benefit of priority to Taiwan Patent Application No. 111142216, filed on Nov. 4, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a composite electrode structure and a method for manufacturing the same, and more particularly to a composite electrode structure for a perovskite solar cell and a method for manufacturing the same.

### BACKGROUND OF THE DISCLOSURE

Recently, a perovskite solar cell has attracted the most attention. The perovskite solar cell has a high light absorption efficiency, such that photons can be quickly separated into electrons and electron holes, and the electrons are transported to an electrode for generation of an electric current. As such, compared to a conventional semiconductor solar cell, the perovskite solar cell can have a higher photoelectric conversion efficiency (PCE).

In addition to materials, a device structure, interface properties, a fill factor, and a series resistance of a solar cell will all affect the photoelectric conversion efficiency of the solar cell. In order to reduce the impact of the series resistance on the photoelectric conversion efficiency, noble metals (such as gold) are used as a back electrode in the related art. However, the noble metals are costly and not suitable for mass production. Therefore, there is still room for improvement in the existing back electrode of the solar cell.

### SUMMARY OF THE DISCLOSURE

In response to the above-referenced technical inadequacy, the present disclosure provides a composite electrode structure and a method for manufacturing the same.

In order to solve the above-mentioned problem, one of the technical aspects adopted by the present disclosure is to provide a composite electrode structure. The composite electrode structure is used as a back electrode of a perovskite solar cell. The composite electrode structure includes a first conductive layer and a second conductive layer. The first conductive layer is used to connect with an electron transporting layer or a hole transporting layer. A material of the first conductive layer is a first light transmitting conductive oxide. The second conductive layer is disposed on the first conductive layer. A material of the second conductive layer is a second light transmitting conductive oxide or a conductive metal.

In order to solve the above-mentioned problem, another one of the technical aspects adopted by the present disclosure is to provide a method for manufacturing a composite electrode structure. The method includes steps of: sputtering to form a first conductive layer onto an electron transporting layer or a hole transporting layer; and sputtering to form a second conductive layer onto the first conductive layer. A material of the first conductive layer is a first light transmitting conductive oxide. A material of the second conductive layer is a second light transmitting conductive oxide or a conductive metal.

Therefore, in the composite electrode structure and the method for manufacturing the same provided by the present disclosure, by virtue of “a first conductive layer being used to connect with an electron transporting layer or a hole transporting layer,” “a material of the first conductive layer being a first light transmitting conductive oxide,” and “a material of the second conductive layer being a second light transmitting conductive oxide or a conductive metal,” manufacturing costs of the perovskite solar cell can be decreased, and a photoelectric conversion efficiency of the perovskite solar cell can be enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a composite electrode structure according to the present disclosure;

FIG. 2 is a schematic side view of a perovskite solar cell according to one embodiment of the present disclosure;

FIG. 3 is a current-voltage diagram of Example 1 and Comparative Example 1; and

FIG. 4 is a schematic side view of the perovskite solar cell according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

The present disclosure provides a composite electrode structure, which can be used as a back electrode of a perovskite solar cell. The composite electrode structure can solve the problem of high costs of a conventional back electrode and have a photoelectric conversion efficiency similar to that of the conventional back electrode.

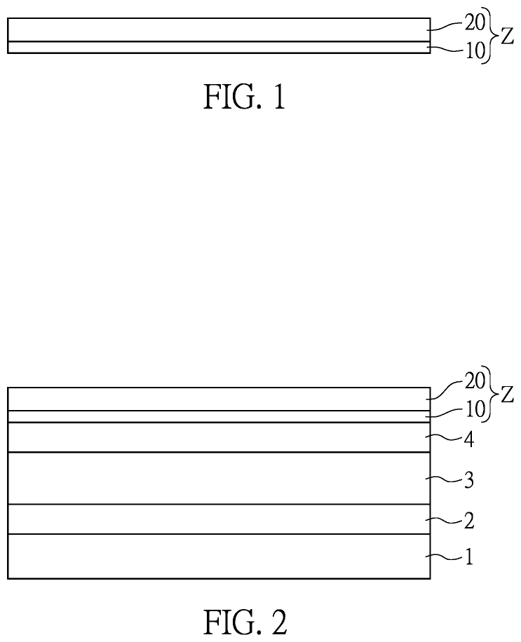

Referring to FIG. 1, a composite electrode structure Z includes a first conductive layer 10 and a second conductive layer 20.

In practice, when being applied to the perovskite solar cell, the composite electrode structure Z contacts an electron transporting layer or a hole transporting layer of the perovskite solar cell via the first conductive layer 10. The first conductive layer 10 has an appropriate energy level, so as to reduce energy loss of carriers (e.g., electrons or holes) that are transported from the electron transporting layer or the hole transporting layer to the first conductive layer 10. The second conductive layer 20 has a low resistance, so as to enhance a collection effect of the carriers. Therefore, when the composite electrode structure Z of the present disclosure is applied to the perovskite solar cell, the perovskite solar cell can have a good photoelectric conversion efficiency.

A material of the first conductive layer 10 is a light transmitting conductive oxide. The light transmitting conductive oxide is selected from the group consisting of indium oxide doped with molybdenum or tungsten (IXO), indium oxide doped with tin (ITO), zinc oxide doped with aluminum (AZO), and zinc oxide doped with indium (IZO), but the present disclosure is not limited thereto.

By being formed from different materials and adjusting manufacturing parameters, the first conductive layer 10 can have various energy levels. Moreover, the energy level of the first conductive layer 10 can also be adjusted by using different materials to form the electron transporting layer or the hole transporting layer, such that the energy level of the first conductive layer 10 can match with a conduction band of the electron transporting layer or a valence band of the hole transporting layer.

For example, 2,2′,7,7′-tetrakis[N,N-di(4-methoxyphenyl)amino]-9,9′-spirobifluorene (spiro-OMeTAD) is a common material of the hole transporting layer, and has a valence band of −5.20 eV. When the first conductive layer 10 is disposed adjacent to the hole transporting layer, the energy level of the first conductive layer 10 is closer to −5.20 eV, thereby decreasing the energy loss of the carriers during transition. The steps for forming the first conductive layer 10 will be described later.

The second conductive layer 20 is disposed on the first conductive layer 10. The second conductive layer 20 has a low resistance, so as to redeem the inadequacy of high resistance of the first conductive layer 10.

A material of the second conductive layer 20 is a light transmitting conductive oxide or a conductive metal. The second conductive layer 20 can have various resistances by selecting different materials to form the second conductive layer 20 and adjusting manufacturing parameters of the second conductive layer 20. When the material of the second conductive layer 20 is the light transmitting conductive oxide, the light transmitting conductive oxide can be selected from the group consisting of indium oxide doped with molybdenum or tungsten (IXO), indium oxide doped with tin (ITO), zinc oxide doped with aluminum (AZO), and zinc oxide doped with indium (IZO), but the present disclosure is not limited thereto. When the material of the second conductive layer 20 is the conductive metal, the conductive metal can be selected from the group consisting of copper, silver, gold, and aluminum. The steps for forming the second conductive layer 20 will be described later.

In an exemplary embodiment, a thickness of the first conductive layer 10 can range from 5 nm to 50 nm, and a thickness of the second conductive layer 20 can range from 50 nm to 200 nm. If the thickness of the first conductive layer 10 is too large, a series resistance of the first conductive layer 10 will be increased. If the thickness of the first conductive layer 10 is too small, the first conductive layer 10 cannot prevent atomic diffusion of the second conductive layer 20, which may negatively influence the device reliability. If the thickness of the second conductive layer 20 is too large, material costs will be unnecessarily increased. If the thickness of the second conductive layer 20 is too small, the second conductive layer 20 cannot protect other layers from contact with the outside.

### FIRST EMBODIMENT

Referring to FIG. 1 and FIG. 2, the perovskite solar cell of a first embodiment of the present disclosure includes a light transmitting electrode 1, an electron transporting layer 2, a perovskite layer 3, a hole transporting layer 4, and a composite electrode structure Z that are sequentially stacked together. The perovskite solar cell shown in FIG. 2 is a positive structure, but the present disclosure is not limited thereto.

Specifically, a material of the light transmitting electrode 1 can be a tin oxide doped with fluorine (FTO). A material of the electron transporting layer 2 can be titanium dioxide. A material of the hole transporting layer 4 can be spiro-OMeTAD. In the composite electrode structure Z, the material of the first conductive layer 10 can be indium oxide doped with molybdenum or tungsten (IXO), and the material of the second conductive layer 20 can be copper.

The first conductive layer 10 of the composite electrode structure Z is disposed on the hole transporting layer 4. In the present disclosure, the hole transporting layer 4 can be directly disposed on the first conductive layer 10 without additionally having inorganic oxide (which is used as a protection layer or a sacrificial layer) disposed therebetween.

It should be noted that the first conductive layer 10 has an energy level that matches with a valence band of the hole transporting layer 4. Specifically, a band gap between the energy level of the first conductive layer 10 and the valence band of the hole transporting layer 4 ranges from 0.1 eV to 0.85 eV. Accordingly, it is easier for holes to be transmitted from the hole transporting layer 4 to the first conductive layer 10, such that energy loss of the holes during transition can be decreased and the photoelectric conversion efficiency can be enhanced.

As mentioned above, the material of the hole transporting layer 4 can be spiro-OMeTAD, so that the valence band of the hole transporting layer 4 is −5.20 eV. Therefore, the energy level of the first conductive layer 10 that matches with the valence band of the hole transporting layer 4 ranges from −4.35 eV to −5.10 eV. However, the present disclosure is not limited thereto. The energy level of the first conductive layer 10 can be adjusted according to different materials of the hole transporting layer 4.

While the first conductive layer 10 has the energy level that matches with the valence band of the hole transporting layer 4, the first conductive layer 10 also has a high resistance. Therefore, in the present disclosure, copper is used as the second conductive layer 20 due to its low resistance, so as to redeem the problem of high resistance of the first conductive layer 10.

In the first embodiment, a method for manufacturing the composite electrode structure includes: stacking the light transmitting electrode 1, the electron transporting layer 2, the perovsite layer 3, and the hole transporting layer 4 to form a laminate sample; and sputtering to form the first conductive layer 10 onto the laminate sample (the hole transporting layer 4) in a DC or pulsed DC sputtering system by using an IXO (indium oxide doped with molybdenum or tungsten) target (e.g., the model IXO-31 provided by Solar Applied Materials Technology Corp.). The thickness of the first conductive layer 10 ranges from 5 nm to 50 nm. In the sputtering process, a distance between the target and the laminate sample is 8 mm, and a sputtering power ranges from 0.1 kW to 1 kW.

It should be noted that the energy level and the resistance of the first conductive layer 10 can be adjusted by different sputtering parameters. In the sputtering process, an atmosphere containing argon gas or an atmosphere containing argon gas and oxygen gas can be used as a sputtering atmosphere. The energy level and a sheet resistance of an IXO film (the first conductive layer 10) can be measured by a Kelvin probe force microscope (KPFM). Flow rates of the argon gas and the oxygen gas in the atmosphere for sputtering, a specific ratio thereof, and the energy level and the sheet resistance of the IXO film are listed in Table 1.

TABLE 1

| No. of IXO film | 1 | 2 | 3 | 4 | 5 | 6 | 7 | 8 |
|---|---|---|---|---|---|---|---|---|
| Flow rate of argon gas | 65 | 65 | 65 | 65 | 65 | 65 | 65 | 65 |
| (sccm) | | | | | | | | |
| Flow rate of oxygen | 0 | 2.5 | 3 | 4.5 | 6.5 | 2.3 | 2.8 | 10 |
| gas (sccm) | | | | | | | | |
| Ratio of flow rate of | — | 26.0 | 21.7 | 14.4 | 10.0 | 28.3 | 23.2 | 6.5 |
| argon gas to flow rate | | | | | | | | |
| of oxygen gas | | | | | | | | |
| Energy level of IXO | −4.36 | −4.38 | −4.53 | −4.66 | −4.79 | −4.58 | −4.70 | −5.08 |
| film (eV) | | | | | | | | |
| Sheet resistance (Ω/□) | 18.5 | 12.9 | 13.2 | 34.2 | 394 | 12.9 | 13.6 | 595.8 |

According to Table 1, the energy level of the IXO film will substantially decrease with an increase of the flow rate of the oxygen gas. In order words, the energy level of the IXO film can be adjusted by changing the flow rate of the oxygen gas, so as to meet the matching requirement of the energy level. The energy level of the IXO film of No. 8 is closest to the valence band of the hole transporting layer 4. Hence, the IXO film of No. 8 can be used as the first conductive layer 10.

Subsequently, the laminate sample with the first conductive layer 10 is placed in the DC or pulsed DC sputtering system. By using a copper target with a purity of 99.999%, the second conductive layer 20 (the material of which is copper) is sputtered onto the laminate sample (the first conductive layer 10). The thickness of the second conductive layer 20 ranges from 50 nm to 150 nm, and an energy level of the second conductive layer 20 is −4.60 eV. In the sputtering process, the distance between the target and the laminate sample is 8 mm, and the sputtering power ranges from 0.1 kW to 1 kW.

It should be noted that, when the second conductive layer 20 is copper, the first conductive layer 10 can prevent copper atoms in the second conductive layer 20 from diffusing toward the perovskite layer 3, thereby enhancing a service life of the perovskite solar cell. Moreover, the low resistance of the copper can redeem the problem of high resistance of the first conductive layer 10.

In addition, compared to deposition, sputtering allows the first conductive layer 10 and the second conductive layer 20 of the present disclosure to be formed at a higher coating speed and to have a higher quality, and is thus suitable for mass production.

### Second Embodiment

The perovskite solar cell of a second embodiment is similar to the perovskite solar cell of the first embodiment. The difference is that the material of the second conductive layer 20 is indium oxide doped with molybdenum or tungsten (IXO). In the second embodiment, the material of the first conductive layer 10 and the material of the second conductive layer 20 are both indium oxide doped with molybdenum or tungsten (IXO), but the flow rate of the oxygen gas during the sputtering process is different (as shown in Table 1). Hence, the first conductive layer 10 and the second conductive layer 20 have different properties. For example, the energy level of the first conductive layer 10 is lower than the energy level of the second conductive layer 20, and the resistance of the first conductive layer 10 is higher than the resistance of the second conductive layer 20.

In the second embodiment, the method for manufacturing the composite electrode structure includes: sequentially stacking the light transmitting electrode 1, the electron transporting layer 2, the perovsite layer 3, and the hole transporting layer 4 to form a laminate sample; sputtering to form the first conductive layer 10 onto the laminate sample in a DC or pulsed DC sputtering system by using an IXO target (provided by Solar applied materials, model: IXO-31). The thickness of the first conductive layer 10 ranges from 5 nm to 50 nm. In the sputtering process, a distance between the target and the laminate sample is 8 mm, and a sputtering power ranges from 0.1 kW to 1 kW.

Subsequently, the laminate sample with the first conductive layer 10 is placed in the DC or pulsed DC sputtering system. The second conductive layer 20 is sputtered to form onto the laminate sample (the first conductive layer 10) by using the same IXO target mentioned above. The thickness of the second conductive layer 20 ranges from 50 nm to 200 nm. In the sputtering process, the distance between the target and the laminate sample is 8 mm, and the sputtering power ranges from 0.1 kW to 1 kW.

Referring to Table 1, the energy level of the IXO film can be adjusted by changing the flow rate of the oxygen gas, so as to meet the matching requirement of the energy level. The energy level of the IXO film of No. 8 is closest to the valence band of the hole transporting layer 4, such that the IXO film of No. 8 can be used as the first conductive layer 10. The IXO film of No. 2 has a low resistance and a high environmental stability, such that the IXO film of No. 2 can be used as the second conductive layer 20.

However, the present disclosure is not limited thereto. Other targets can also be used to form a conductive film, such as an ITO (indium oxide doped with tin) target, an AZO (zinc oxide doped with aluminum) target, or an IZO (zinc oxide doped with indium) target.

In order to prove that the composite electrode structure Z of the present disclosure can replace the back electrode of the conventional perovskite solar cell, a perovskite solar cell that uses the composite electrode structure Z (Example 1) based on the structure of the first embodiment is manufactured. The perovskite solar cell of Example 1 and the conventional perovskite solar cell that uses a gold electrode (Comparative Example 1) are subjected to a photoelectric conversion efficiency test for comparison.

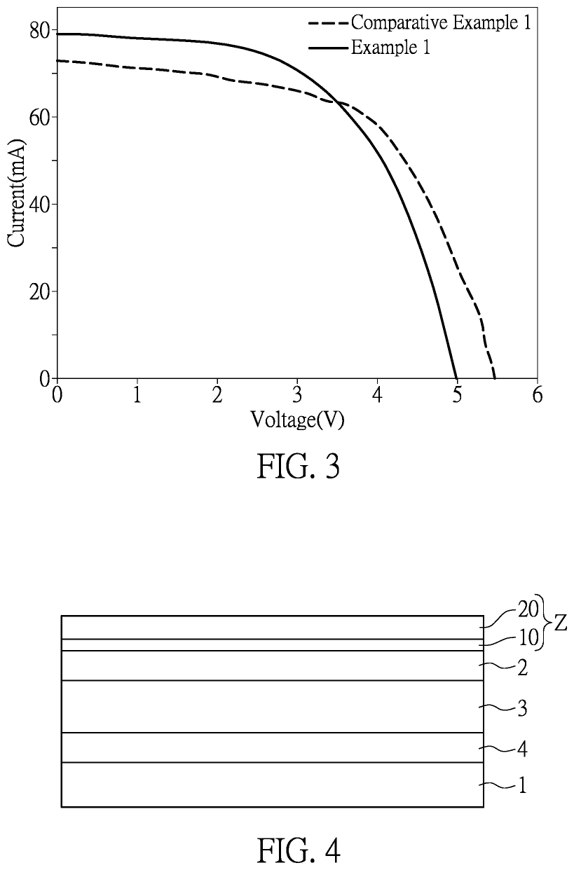

In the photoelectric conversion efficiency test, a xenon lamp is applied to a solar simulator (the model PEC-L15 provided by Peccell Technologies, Inc.) to simulate a solar light source. In addition, a correction sheet (provided by Newport KG3) is used to correct a power supply (model: Keithley 2400), which has a light intensity of 1 Sun (equal to 100 mW/cm²), so as to provide biasing to components and detect a photo current, a short-circuit current (I_{SC}), a short-circuit current density (J_{SC}), an open-circuit voltage (V_{OC}), a fill factor (FF), and a photoelectric conversion efficiency (PCE) of the solar cell. An I-V curve analysis software of version 2.3 (provided by Peccell Technologies, Inc.) is used to obtain a J-V curve, and the results are shown in FIG. 3 and Table 2.

TABLE 2

| | | Comparative |
|---|---|---|
| | Example 1 | Example 1 |
| short-circuit current (I_{SC}) (mA) | 78.75 | 72.98 |
| short-circuit current density (J_{SC}) | 20.09 | 18.42 |
| (mA/cm²) | | |
| open-circuit voltage (V_{OC}) (V) | 4.987 | 5.480 |
| fill factor (FF) | 0.567 | 0.575 |
| photoelectric conversion | 11.36 | 11.61 |
| efficiency (PCE) (%) | | |

According to FIG. 3 and the results in Table 2, the perovskite solar cell of Example 1 can have properties similar to those of the perovskite solar cell of Comparative Example 1. In terms of costs, the composite electrode structure of the present disclosure has low manufacturing costs. Therefore, the composite electrode structure of the present disclosure can replace the conventional back electrode, and can be applied in the perovskite solar cell.

Referring to FIG. 4, when the perovskite solar cell is in a negative structure, the perovskite solar cell includes the light transmitting electrode 1, the hole transporting layer 4, the perovskite layer 3, the electron transporting layer 2, and the composite electrode structure Z that are sequentially stacked. The perovskite solar cell shown in FIG. 4 is in a negative structure, but the present disclosure is not limited thereto. Specifically, the composite electrode structure Z is disposed on the electron transporting layer 2 via the first conductive layer 10 without having inorganic oxide (which is used as a protection layer or a sacrifice layer) disposed therebetween. In order words, the electron transporting layer 2 can be directly disposed on the first conductive layer 10.

As mentioned above, by adjusting the manufacturing parameters, the first conductive layer 10 can have an energy level that matches with a conduction band of the electron transporting layer 2. Specifically, a band gap between the energy level of the first conductive layer 10 and the conduction band of the electron transporting layer 2 ranges from 0.1 eV to 0.85 eV. Therefore, electrons may easily transit from the electron transporting layer 2 to the first conductive layer 10, such that the energy loss can be decreased and the photoelectric conversion efficiency of the perovskite solar cell can be enhanced.

### BENEFICIAL EFFECTS OF THE EMBODIMENTS

In conclusion, in the composite electrode structure and the method for manufacturing the same provided by the present disclosure, by virtue of “a first conductive layer being used to connect with an electron transporting layer or a hole transporting layer,” “a material of the first conductive layer being a first light transmitting conductive oxide,” and “a material of the second conductive layer being a second light transmitting conductive oxide or a conductive metal,” the manufacturing costs of the perovskite solar cell can be decreased, and the photoelectric conversion efficiency of the perovskite solar cell can be enhanced.

Further, by sputtering to form the first conductive layer and the second conductive layer of the present disclosure and adjusting the flow rate of the oxygen gas, the energy level of the first conductive layer can be controlled, thereby decreasing the energy loss for the transmission of the carriers. Specifically, the energy gap between the energy level of the first conductive layer and the valence band of the adjacent hole transporting layer or the energy gap between the energy level of the first conductive layer and the conduction band of the adjacent electron transporting layer ranges from 0.1 eV to 0.85 eV. Therefore, the perovskite solar cell can have an advantage of high photoelectric conversion efficiency.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A composite electrode structure, which is used as a back electrode of a perovskite solar cell, the composite electrode structure comprising:
a first conductive layer used to connect with an electron transporting layer or a hole transporting layer, wherein a material of the first conductive layer is a first light transmitting conductive oxide; and
a second conductive layer disposed on the first conductive layer, wherein a material of the second conductive layer is a second light transmitting conductive oxide or a conductive metal.

2. The composite electrode structure according to claim 1, wherein, when the first conductive layer is connected with the electron transporting layer, a band gap between an energy level of the first conductive layer and a conduction band of the electron transporting layer ranges from 0.1 eV to 0.85 eV; wherein, when the first conductive layer is connected with the hole transporting layer, a band gap between the energy level of the first conductive layer and a valence band of the hole transporting layer ranges from 0.1 eV to 0.85 eV.

3. The composite electrode structure according to claim 1, wherein an energy level of the first conductive layer ranges from −4.35 eV to −5.10 eV.

4. The composite electrode structure according to claim 1, wherein the first light transmitting conductive oxide is selected from the group consisting of indium oxide doped with molybdenum or tungsten, indium oxide doped with tin, zinc oxide doped with aluminum, and zinc oxide doped with indium.

5. The composite electrode structure according to claim 1, wherein a thickness of the first conductive layer ranges from 5 nm to 50 nm.

6. The composite electrode structure according to claim 1, wherein a thickness of the second conductive layer ranges from 50 nm to 200 nm.

7. The composite electrode structure according to claim 1, wherein the second light transmitting conductive oxide is selected from the group consisting of indium oxide doped with molybdenum or tungsten, indium oxide doped with tin, zinc oxide doped with aluminum, and zinc oxide doped with indium; wherein the conductive metal is selected from the group consisting of copper, silver, gold, and aluminum.

8. The composite electrode structure according to claim 1, wherein an energy level of the first conductive layer is lower than an energy level of the second conductive layer, and a resistance of the first conductive layer is higher than a resistance of the second conductive layer.

9. A method for manufacturing a composite electrode structure, comprising:
sputtering to form a first conductive layer onto an electron transporting layer or a hole transporting layer, wherein a material of the first conductive layer is a first light transmitting conductive oxide; and
sputtering to form a second conductive layer onto the first conductive layer, wherein a material of the second conductive layer is a second light transmitting conductive oxide or a conductive metal.

10. The method according to claim 9, wherein the first conductive layer is sputtered in an atmosphere containing argon gas and oxygen gas, and a ratio of a flow rate of the argon gas to a flow rate of the oxygen gas ranges from 6.0 to 26.0.

11. The method according to claim 9, wherein a sputtering power for sputtering the first conductive layer ranges from 0.1 kW to 1 kW.

12. The method according to claim 9, wherein an energy level of the first conductive layer is lower than an energy level of the second conductive layer, and a sheet resistance of the first conductive layer is higher than a sheet resistance of the second conductive layer.
